(19) United States
(12) Patent Application Publication
(10) Pub. No.: US 2013/0017632 A1
(43) Pub. Date: Jan. 17, 2013

(54) METHOD FOR MANUFACTURING LIGHT EMITTING DIODE

(71) Applicant: PIN-CHUAN CHEN, Hukou (TW)

(72) Inventor: PIN-CHUAN CHEN, Hukou (TW)

(73) Assignee: ADVANCED OPTOELECTRONIC TECHNOLOGY, INC., Hsinchu Hsien (TW)

(21) Appl. No.: 13/337,126

(22) Filed: Dec. 25, 2011

(30) Foreign Application Priority Data
Jul. 15, 2011 (CN) 201110198809.6

(51) Int. Cl. H01L 33/52

(52) U.S. Cl. 438/28; 257/E33.059

(57) ABSTRACT

A method for manufacturing LEDs (light emitting diodes) includes steps: providing a substrate; attaching an adhesive layer on the substrate; forming a blocking layer on the adhesive layer, the blocking layer having a plurality of first holes and second holes alternating with and spaced from the first holes; forming a conductive layer including first leads and second leads in the first holes and the second holes; removing the blocking layer; forming a housing layer on the adhesive layer, the housing layer having a plurality of cavities to expose the first leads and second leads; fixing chips on the first leads and electrically connecting the chips with the first and second leads; forming encapsulants in the cavities to seal the chips; and removing the substrate and adhesive layer from the housing layer and the conductive layer.

### BACKGROUND

1. Technical Field

The present disclosure relates to a method for manufacturing light emitting diodes, and more particularly, to a method for manufacturing ultra-thin light emitting diodes.

2. Description of Related Art

As a new type of light source, LEDs are widely used in various applications. A typical LED includes a base, a pair of leads fixed on the base, a housing formed on the leads, a light emitting chip fixed in the housing and electrically connected to the leads via wires, and an encapsulant attached on the housing and sealing the light emitting chip. The typical LED often has a large thickness due to at least one of the base and the leads should be thick enough for providing sufficient strength when forming the housing and the encapsulant. Thus, the typical LED cannot be made thin to meet illumination requirements of thin products.

What is needed, therefore, is a method for manufacturing light emitting diodes which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows a first process of manufacturing light emitting diodes in accordance with an embodiment of the present disclosure.

FIG. 2 shows a second process of manufacturing light emitting diodes in accordance with the embodiment of the present disclosure.

FIG. 3 shows a third process of manufacturing light emitting diodes in accordance with the embodiment of the present disclosure.

FIG. 4 shows a fourth process of manufacturing light emitting diodes in accordance with the embodiment of the present disclosure.

FIG. 5 shows a fifth process of manufacturing light emitting chips in accordance with the embodiment of the present disclosure.

FIG. 6 shows a sixth process of manufacturing light emitting diodes in accordance with the embodiment of the present disclosure.

FIG. 7 shows a seventh process of manufacturing light emitting diodes in accordance with the embodiment of the present disclosure.

FIG. 8 shows an eighth process of manufacturing light emitting diodes in accordance with the embodiment of the present disclosure.

FIG. 9 shows a light emitting diode which has been manufactured after the processes of FIGS. 1-8.

### DETAILED DESCRIPTION OF THE EMBODIMENTS

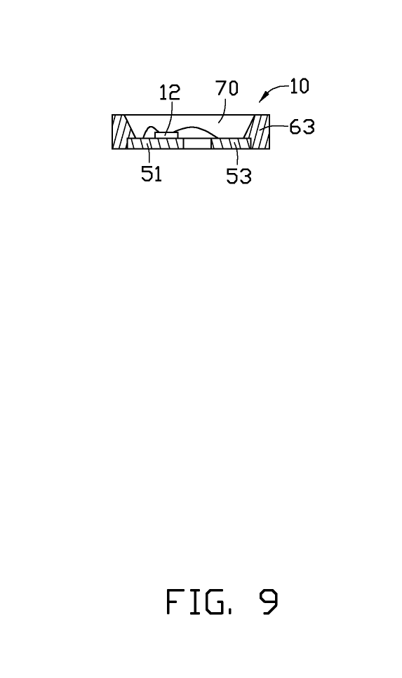

As shown in FIG. 9, a light emitting diode 10 manufactured according to a method of the present disclosure is shown. Details of the method for manufacturing the light emitting diode 10 in accordance with an embodiment of the present disclosure is described below.

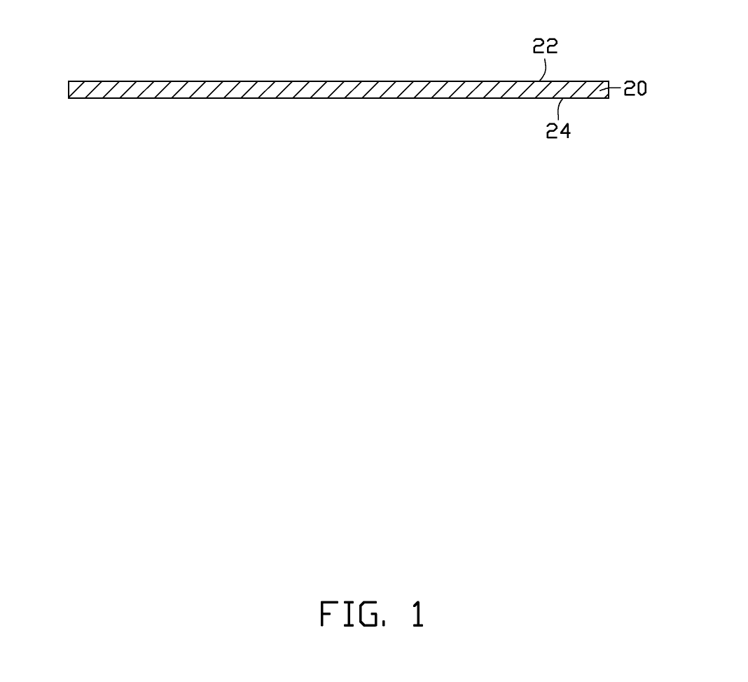

As shown in FIG. 1, firstly, a temporary substrate 20 is provided. The substrate 20 may be made of metal, ceramic or other suitable material which is rigid and has a sufficient strength to resist an external force acting thereon. The substrate 20 has a flat top face 22 and a flat bottom face 24 opposite to the top face 22.

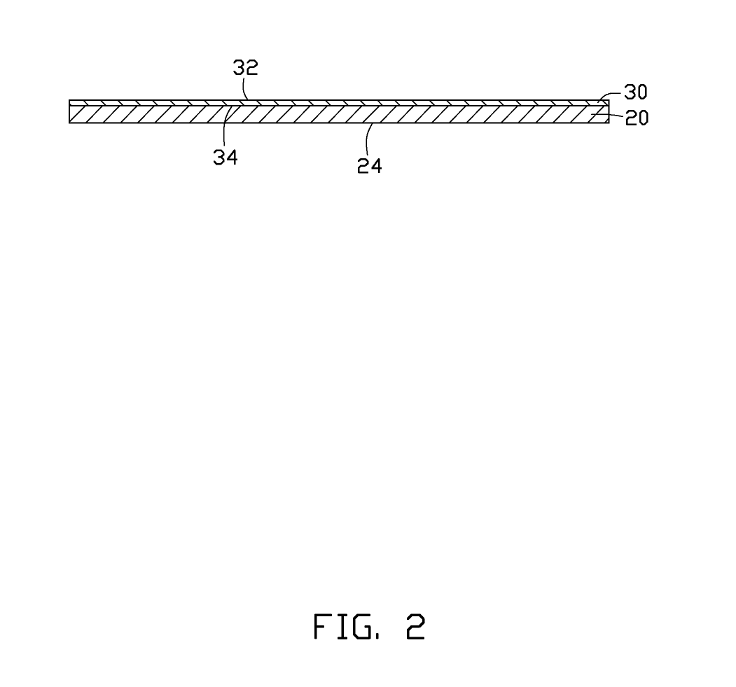

As shown in FIG. 2, a flexible adhesive layer 30 is then attached on the top face 22 of the substrate 20. The adhesive layer 30 may be made of electrically conductive materials. In this embodiment, the adhesive layer 30 is an electrically conductive tape which is adhesive at both bottom and top faces 34, 32 thereof. Alternatively, in another embodiment, the adhesive layer may be adhesive only at the bottom face 34 thereof which connects with the substrate 20.

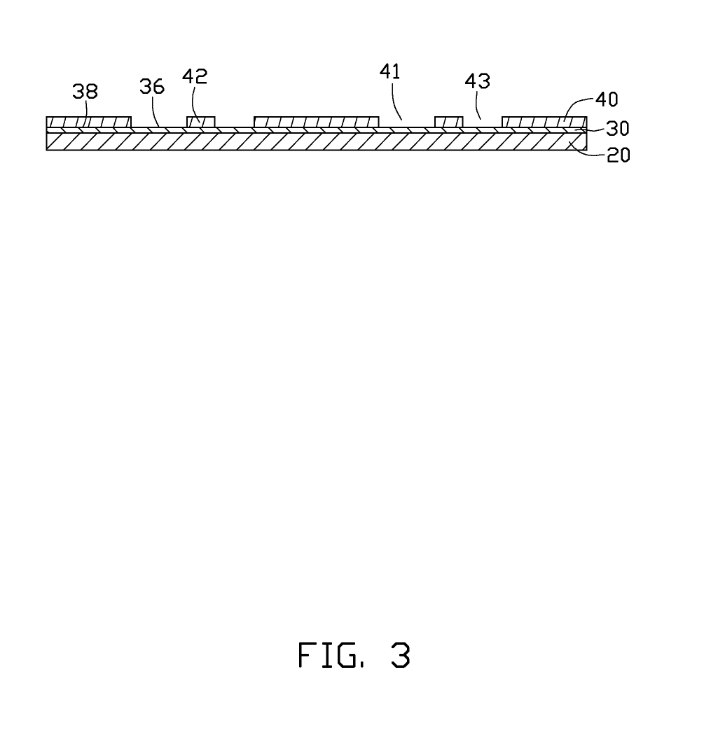

A blocking layer 40 is then formed on the adhesive layer 20, as shown in FIG. 3. The blocking layer 40 may be formed by sputtering or smearing. The blocking layer 40 defines a plurality of first through holes 41 and second through holes 43 therein via a photolithograph technology. The first through holes 41 and the second through holes 43 are alternately arranged above the adhesive layer 30. Each first through hole 41 has an inner diameter larger than that of the second through hole 43. Each first through hole 41 is spaced from and does not communicate with adjacent second through holes 43. An island 42 is formed between every two adjacent first and second through holes 41, 43. The islands 42 are spaced from the other parts of the blocking layer 40. The adhesive layer 30 has a plurality of areas 36 exposed in the first and second through holes 41, 43, and remaining areas 38 covered by the blocking layer 40.

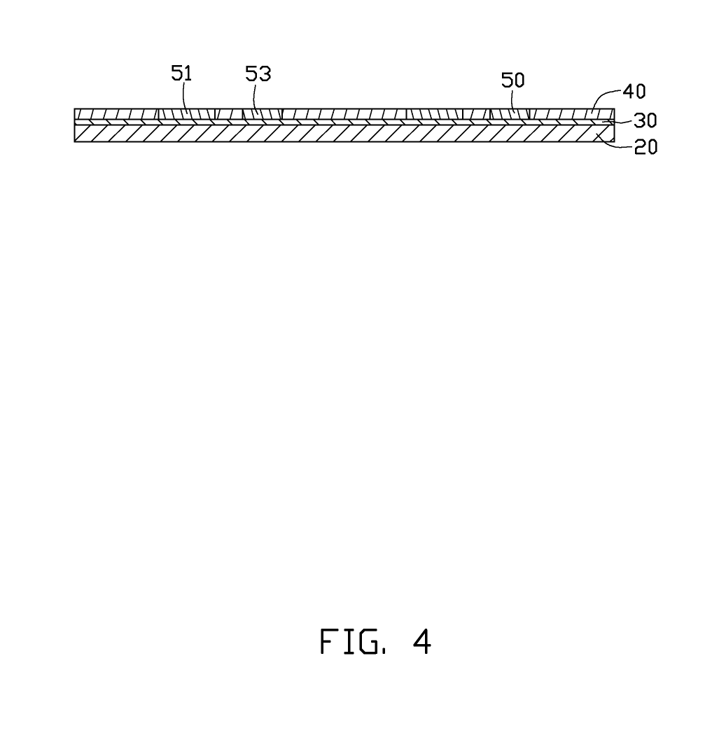

As shown in FIG. 4, a conductive layer 50 is formed in the first through holes 41 and the second through holes 43. The conductive layer 50 may be formed on the adhesive layer 30 by electroplating metal on the adhesive layer 30. The metal of the conductive layer 50 may be selected from aluminum, silver, copper or other materials having good electrically conductive capability. The conductive layer 50 has a thickness the same as that of the blocking layer 40. The conductive layer 50 includes a plurality of pairs of first lead 51 and second lead 53. The first leads 51 are received in the first through holes 41 and the second leads 53 are received in the second through holes 43, respectively. The first leads 51 are spaced from and do not connect with the second leads 53. Each first lead 51 has an area larger than that of each second lead 53. The first leads 51 and the second leads 53 cover and connect the areas 36 of the blocking layer 30 exposed in the first and second through holes 41, 43.

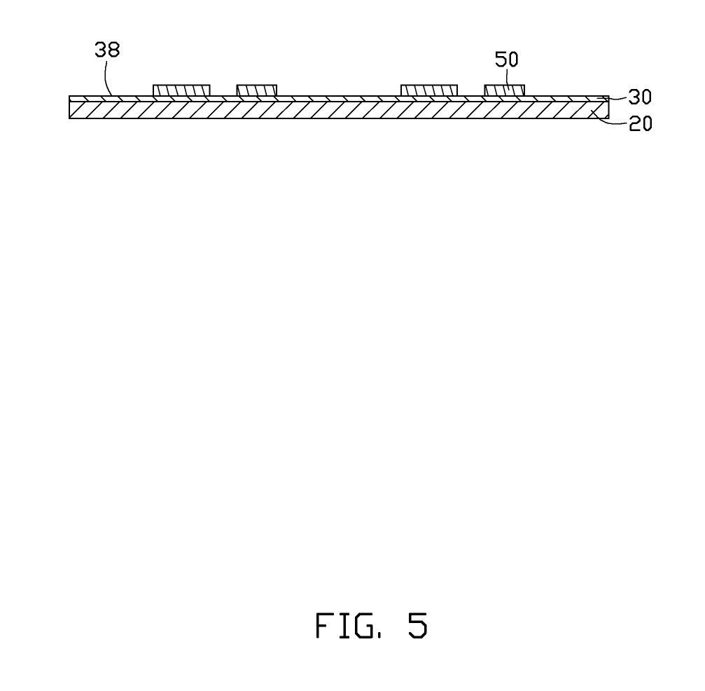

As shown in FIG. 5, the blocking layer 40 is removed from the adhesive layer 30. The removal of the blocking layer 40 may be implemented by etching. The remaining areas 38 of the adhesive layer 30 which are covered by the blocking layer 40 in the previous processes of FIGS. 3-4, are now exposed again.

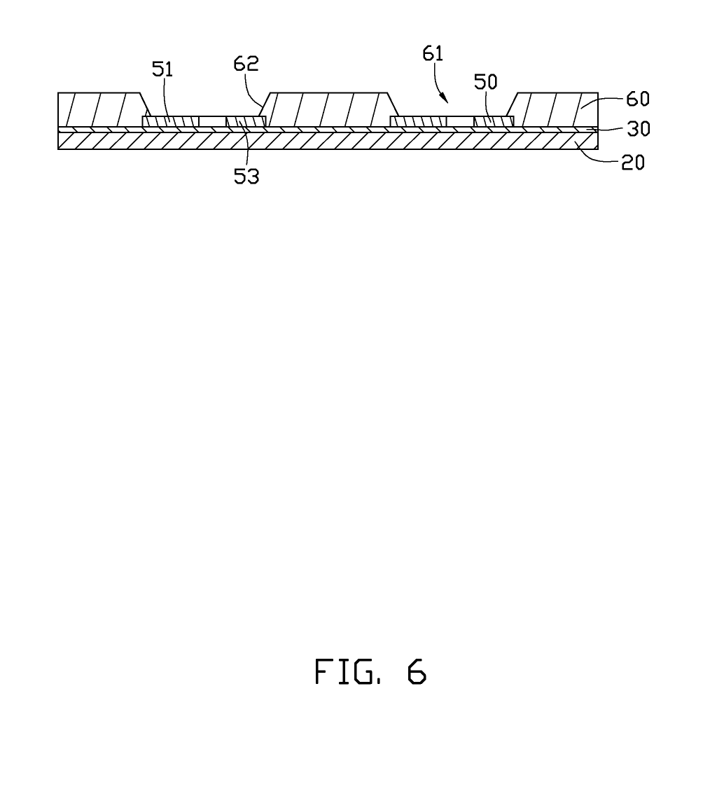

A housing layer 60 is formed on the now exposed areas 38 of the adhesive layer 30 as shown in FIG. 6. The housing layer 60 may be made of PPA (polyphthalamide), epoxy or other plastic materials. The housing layer 60 may be formed on the adhesive layer 30 by injection-molding, transfer-molding or other suitable methods. The housing layer 60 has a thickness larger than that of the conductive layer 50. The housing layer 60 covers opposite ends of each pair of first lead 51 and second lead 53. The housing layer 60 defines a plurality of cavities 61 therein. Each pair of first lead 51 and second lead 53, except the opposite ends thereof which are embedded in the housing layer 60, are exposed in a corresponding cavity 61. Each cavity 61 has an inner diameter gradually increasing from a bottom towards a top of the housing layer 60.

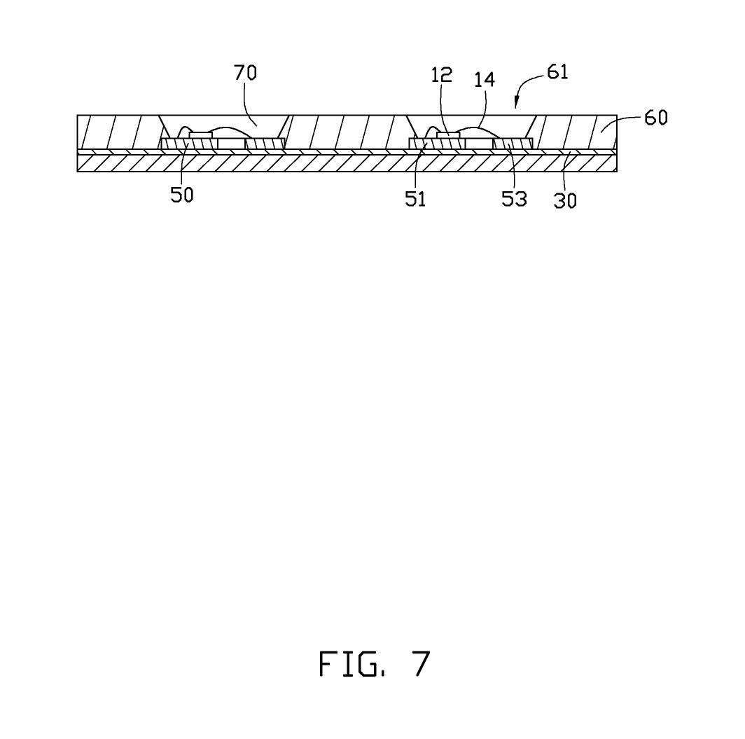

As shown in FIG. 7, a plurality of light emitting chips 12 are fixed in the cavities 61, respectively. Each light emitting chip 12 may be a GaN chip, an InGaN chip, an AlInGaN chip or other light emitting semiconductor chips. Each light emitting chip 12 is fixed on a corresponding first lead 51 and electrically connected to the corresponding first lead 51 and an adjacent second lead 53 via two wires 14. A transparent material such as epoxy or silicon may be injected into the cavities 61 to form a plurality of encapsulants 70. The encapsulants 70 seal the light emitting chips 12 and the wires 14. The encapsulants 70 are attached on inner circumferential faces 62 of the housing layer 60 defining the cavities 61. Alternatively, if necessary, fluorescent particles, for example, YAG (yttrium aluminum garnet) particles, may be added in the transparent material, whereby when light from a light emitting chip 12 through a corresponding encapsulant 70, color of the light can be changed to a different color.

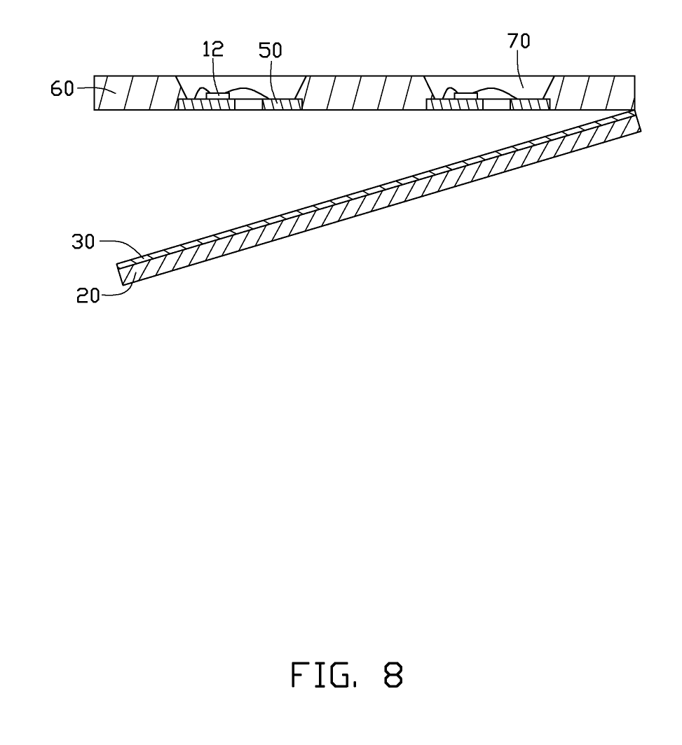

As shown in FIG. 8, the adhesive layer 30 is then detached from the housing layer 30 and the conductive layer 50. The detachment of the adhesive layer 30 from the housing layer 60 and the conductive layer 50 may use mechanical methods such as tearing. An adhering force between the adhesive layer 30 and the housing layer 60 is less than that between the adhesive layer 30 and the substrate 20, whereby the substrate 20 is detached together with the adhesive layer 20 from the housing and conductive layers 60, 50. Accordingly, a semi-finished product including a plurality of LEDs each having a corresponding LED chip 12 is obtained.

Finally, the semi-finished product is severed by cutting the housing layer 60 to form a plurality of individual LEDs 10 each having a structure as that shown in FIG. 9. Each LED 10 includes a pair of first lead 51 and second lead 53, a housing 63 fixed on the first lead 51 and the second lead 53, one light emitting chip 12 mounted on the first lead 51 and one encapsulant 70 sealing the light emitting chip 12.

Since the substrate 20 is removed from the LED 10 after molding the housing layer 60 and the encapsulants 70, the LEDs 10 can be manufactured very thin. Furthermore, the conductive layer 50 formed by electroplating also has a relatively small thickness, further facilitating reduction of the thickness of the LED 10.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. A method for manufacturing LEDs (light emitting diodes) comprising:
providing a substrate;
providing an adhesive layer on the substrate;
forming a blocking layer on the adhesive layer, the blocking layer defining a plurality of first holes and second holes alternating with and spaced from the first holes;
forming a conductive layer comprising a plurality of pairs of first lead and second lead in the first holes and the second holes, respectively;
removing the blocking layer to expose part of the adhesive layer uncovered by the conductive layer;
forming a housing layer on the exposed part of the adhesive layer and partially covering the conductive layer, the housing defining a plurality of cavities to expose the plurality of pairs of first lead and second lead, wherein each pair of first lead and second lead is exposed in a corresponding cavity;
fixing a plurality of light emitting chips in the cavities and electrically connecting the light emitting chips with the pairs of first lead and second lead, respectively;
forming a plurality of encapsulants in the cavities;
removing the adhesive layer together with the substrate from the housing layer; and
cutting the housing layer to form the LEDs each including a corresponding light emitting chip.

2. The method of claim 1, wherein the substrate is rigid and the adhesive layer is flexible.

3. The method of claim 1, wherein the first holes and the second holes extend from a bottom face to a top face of the blocking layer to expose a plurality of areas of a top face of the adhesive layer.

4. The method of claim 3, wherein the first holes and the second holes are defined by photolithograph.

5. The method of claim 3, wherein the first leads and the second leads directly connect the areas of the top face of the adhesive layer exposed in the first holes and the second holes when forming the conductive layer.

6. The method of claim 5, wherein the adhesive layer is electrically conductive.

7. The method of claim 6, wherein the adhesive layer is an adhesive tape.

8. The method of claim 6, wherein the conductive layer is formed by electroplating a metal material in the first holes and the second holes.

9. The method of claim 1, wherein each first lead has an area larger than that of each second lead.

10. The method of claim 3, wherein other areas of the top face of the adhesive layer are exposed after removing the blocking layer, and the housing layer joins the other areas of the top face of the adhesive layer when forming the housing layer.

11. The method of claim 1, wherein the housing layer has a thickness larger than that of the substrate.

12. The method of claim 1, wherein an adhering force between the housing layer and the adhesive layer is smaller than that between the adhesive layer and the substrate.

13. The method of claim 12, wherein the adhesive layer is removed from the housing layer by tearing.

14. The method of claim 1, wherein the housing layer and the substrate are made of different materials.

15. The method of claim 1, wherein each light emitting chip is fixed on a corresponding first lead.

16. The method of claim 1, wherein both of a top face and a bottom face of the adhesive layer are adhesive.

17. The method of claim 1, wherein only a bottom face of the adhesive layer is adhesive.
